(19) United States
(12) Patent Application Publication
(10) Pub. No.: US 2005/0016859 A1
(43) Pub. Date: Jan. 27, 2005

(54) [PROCESS FOR FABRICATING BUMPS]

(76) Inventors: Min-Lung Huang, Kaohsiung (TW); Chi-Long Tsai, Taitung County (TW); Chao-Fu Weng, Tainan (TW); Ching-Huei Su, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,020

(22) Filed: Jun. 14, 2004

(30) Foreign Application Priority Data
Jul. 22, 2003 (TW) 92119937

(51) Int. Cl. C25D 5/02; H01L 21/288

(52) U.S. Cl. 205/123; 205/122

(57) ABSTRACT

A bump fabrication process is provided. A substrate having a plurality of openings of various widths thereon is provided. The substrate is dipped into an electrolytic solution. A step current that increases gradually is provided to the solution to perform an electroplating operation so that the conductive material is deposited inside the openings to form bumps with uniform thickness.

### CROSS REFERENCE TO RELATED APPLICATIONS

This application claims the priority benefit of Taiwan application serial no. 92119937, filed Jul. 7, 2003.

### BACKGROUND OF INVENTION

1. Field of the Invention

The present invention relates to a process for fabricating bumps. More particularly, the present invention relates to a process of forming a plurality of bumps with uniform thickness on a substrate by electroplating.

2. Description of the Related Art

With great advances in information technologies, multimedia market continues to expand. The techniques for packaging integrated circuits also reflect the need for digital processing, networking, area connection and functional personalization in electronic products. To increase the processing speed, multi-functional capacity, level of integration and compactness, miniaturization and densification of integrated circuit packages is an ongoing activity. As a result, high-density integrated circuit packages including ball grid array (BGA), chip-scale package (CSP), flip chip (F/C), multi-chip module (MCM) have been developed. The so-called integrated circuit package density is a measurement for the number of pins that can be accommodated per unit area. Since reducing the length of layout wires is highly beneficial to signal transmission for a high-density integrated circuit package, bumps have become a popular means of electrical connection inside a high-density package.

FIG. 1 is a schematic cross-sectional view of conventional bumps over a substrate. To fabricate bumps on a wafer, a substrate 100 with a plurality of bonding pads 102 and a passivation layer 104 thereon is provided. Thereafter, an under-bump-metallurgy (UBM) layer 106 is formed over the substrate 100 to serve as a junction interface between a subsequently formed bump 112 and the bonding pads 102. A photoresist layer 108 is formed over the substrate 100. The photoresist layer 108 has a plurality of openings 110 that exposes the bonding pads 102 and determines the location of the bumps 112.

At present, face-to-face chip bonding to form a multi-chip package is frequently adopted to increase packing density. In general, bumps having different pitch and height must be produced on the same chip or carrier. To produce bumps 112 having different size and height after a reflow operation, the openings 110 in the photoresist layer are often designed to have different widths according to demands. Through setting the height level and width of each opening 110, the volume of solder material deposited inside each opening 110 can be deduced. Afterwards, the substrate 100 is dipped into a pool of electrolytic solution and a direct current (DC) is passed through the solution to begin electroplating. At the end of the electroplating operation, bumps 112 of various volumes are produced inside the openings 110.

In the conventional bump fabrication process, a single direct current is passed to carry out the electroplating operation. When the opening is too narrow or too deep, that is, the aspect ratio of the opening is greater than 1.2, mass transfer of the electrolytic solution is usually poor. Under such circumstances, the metallic ions within the electrolytic solution can hardly diffuse into the openings. In other words, the conventional process of forming bumps by passing a direct current into an electrolytic solution can hardly produce a uniform bump thickness inside each opening due to variant electroplating rates in the openings with different widths.

Furthermore, as the aspect ratio of the opening in the photoresist layer becomes larger than 1.2, some conductive material may gradually deposit in the corner regions between the upper surface and the sidewall of the opening. Hence, the opening may be blocked before the interior of the opening is fully filled and the space inside the opening is not fully filled. Because voids are formed within the bumps, the height level of the bump may vary considerably.

### SUMMARY OF INVENTION

Accordingly, one object of the present invention is to provide a process for fabricating bumps on a substrate. The process utilizes an increasing step current to carry out an electroplating operation so that the bumps have a uniform thickness.

To achieve these and other advantages and in accordance with the purpose of the invention, as embodied and broadly described herein, the invention provides a bump fabrication process. First, a substrate having a plurality of bonding pads and a passivation layer thereon is provided. The passivation layer has openings that expose the bonding pads. Thereafter, a photoresist layer is formed over the substrate. The photoresist layer has a plurality of openings having different widths. The openings are formed in locations to correspond to the bonding pads. The substrate is immersed into an electrolytic solution and then an increasing step current is applied to carry out an electroplating operation so that bumps with an uniform thickness are formed over the substrate.

In one embodiment of this invention, the step current lies between a low current Iₘᵢₙ and a high current Iₘₐₓ. The current Iₘᵢₙ is the smallest current applied to start the electroplating operation and Iₘₐₓ is the largest permissible current for performing the electroplating operation.

In one embodiment of this invention, the step current may comprise a number of linear currents. In addition, there are intervals without providing any current between providing the linear currents, so that the metallic ions within the electrolytic solution are provided with enough time to diffuse into the openings.

Furthermore, the step current may comprise a series of pulse currents including a peak current and a trough current. The peak current of the pulse currents is set between Iₘᵢₙ and Iₘₐₓ and the trough current is set to a positive value smaller than Iₘᵢₙ, zero or a negative value. Obviously, the step current may comprise a combination of at least a pulse current and a plurality of linear currents.

In this invention, an increasing step current is applied to perform an electroplating operation so that the metallic ions within the electrolyte has sufficient time to diffuse into the openings on the substrate. Ultimately, bumps with an uniform thickness are formed inside various openings. In addition, the step current may include a plurality of pulse currents. If the trough current of the pulse current falls to a negative value, the conductive material deposited near the corner regions between the top and sidewalls of the openings will be electrolyzed to prevent the conductive material block the mouth of the opening. Hence, the conductive material can fills into the openings during the electroplating operation without the formation of voids. Since novoids are formed inside the bump, the subsequent lowering of the bump height after a reflow process can be avoided.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of conventional bumps over a substrate.

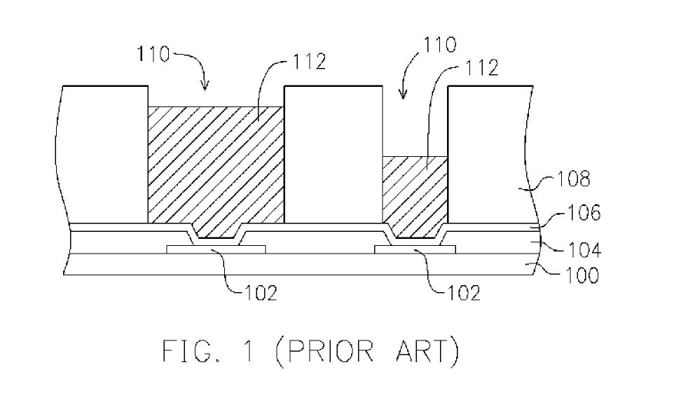

FIG. 2 is a flow chart showing the steps for forming bumps on a substrate according to one preferred embodiment of this invention.

FIGS. 3A and 3B are graphs showing the current versus time relation for performing an electroplating operation according to this invention.

FIGS. 4A through 4C are graphs showing alternative current versus time relation for performing an electroplating operation according to this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

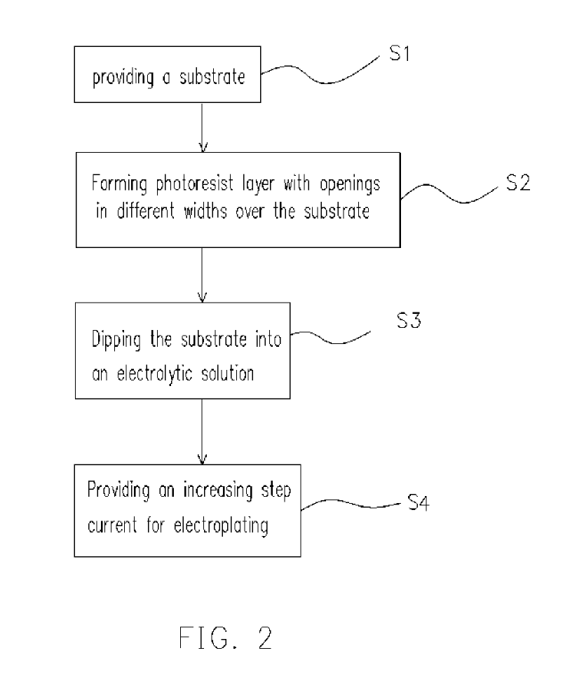

FIG. 2 is a flow chart showing the steps for forming bumps on a substrate according to one preferred embodiment of this invention. First, a substrate, such as a wafer having a plurality of bonding pads and a passivation layer thereon, is provided (step S1). The passivation layer on the surface of the substrate exposes the bonding pads. Thereafter, a photoresist layer is formed over the substrate (step S2). The photoresist layer has a plurality of openings with having different widths, and each opening is positioned over one bonding pad. Next, the substrate is dipped into an electrolytic solution (step S3). Finally, an increasing step current is applied to performing an electroplating operation (step S4). Because a lower current is used in the front part of the electroplating operation, the metallic ions within the electrolytic solution have sufficient time to diffuse into narrow photoresist openings and adhere to the bonding pad. However, as the aspect ratio of the photoresist opening gradually reduces due to deposition of the metallic material, the electric current is increased to speed up the electroplating process. Hence, through the stepwise increase of the current, bumps having a uniform thickness are formed inside various openings above the substrate.

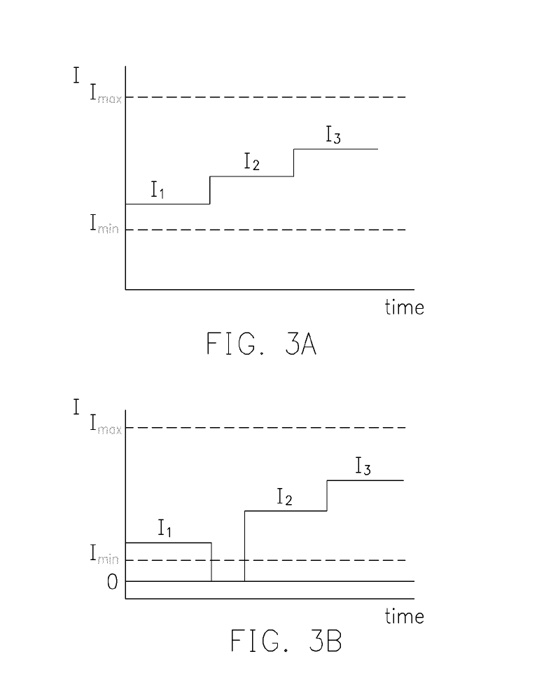

FIGS. 3A and 3B are graphs showing the current versus time relation for performing an electroplating operation according to this invention. The increasing step current applied to the electrolytic solution as shown in FIG. 3A comprises a plurality of linear currents (three linear currents I1, I2 and I3). The linear currents (I1, I2 and I3) are set up between Iₘᵢₙ and Iₘₐₓ where Iₘᵢₙ is the smallest current to start the electrolytic operation and Iₘₐₓ is the largest permissible current for performing the electrolytic operation.

Halfway through the electroplating operation with linear currents (I1, I2 and I3), the supply of current to the electrolytic solution may be temporarily shut down as shown in FIG. 3B. The temporary shutdown of current provides time for the metallic ions to diffuse into the openings. Hence, the electroplating rate inside various photoresist openings is synchronized when the passage of current through the electrolytic solution is resumed, thus producing bumps with a uniform thickness. Although only one shutdown of the current is shown during the electroplating operation in FIG. 3B, the actual number of shutdowns normally varies depending on the actual requirements.

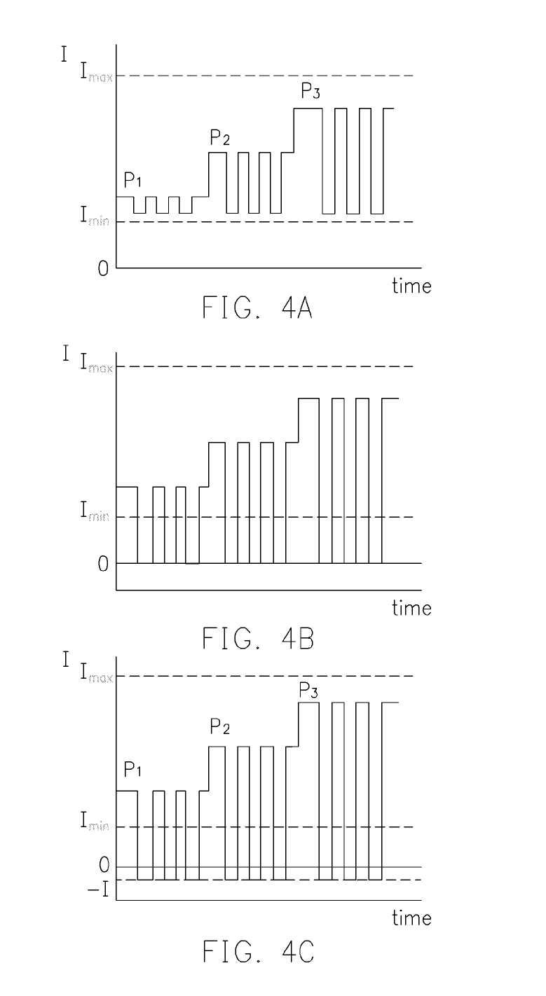

FIGS. 4A through 4C are graphs showing alternative current versus time relation for performing an electroplating operation according to this invention. As shown in FIGS. 4A to 4C, the step current actually comprises of a series of pulse currents. In this embodiment, each step current is actually a combination of three identical pulse currents (P1, P2 and P3). Each pulse current includes a peak current and a trough current, while the peak current is between Iₘᵢₙ and Iₘₐₓ. The trough current is either a positive current smaller than Iₘᵢₙ as shown in FIG. 4A, or zero (zero current) as shown in FIG. 4B or the trough current is a negative current as shown in FIG. 4C. If the trough current of the pulse currents (P1, P2 and P3) is a positive current smaller than Iₘᵢₙ or zero, the pulse current is an on/off pulse current. In other words, no current is applied to the electrolytic solution for a brief period during a running cycle of the on/off pulse currents, so that the metallic ions can have sufficient time to diffuse into the openings. On the other hand, if the trough current of the pulse current (P1, P2 and P3) is a negative current smaller than Iₘᵢₙ, the pulse current is a periodical reverse current. In other words, during the period of providing the reverse current, instead of electroplating, the electrolysis reaction occurs to the plated material. Thus, a portion of the conductive material deposited to the corner regions between the upper surface and the sidewall of the opening will be electrolyzed, thus preventing the blocking of the mouth for openings during filling the openings. By providing the reverse current, formation of voids inside the bump are avoided and the bump height will not become lower after a reflow process.

Of course, according to the process described in this invention, the step current may comprise a combination of at least one pulse current and a plurality of linear currents (not shown). Since the method of controlling the step current is similar to the method described above, the operating details are not repeated.

In summary, the bump fabrication process according to this invention at least includes the following advantages:

1. By applying an increasing step current to an electrolytic solution, the metallic ions within the electrolytic solution has enough time to diffuse into the narrow openings in the photoresist layer. Hence, the electroplating rate inside openings of variant widths is constant and the thickness of the bump inside each opening is uniform.

2. If a reverse pulse current is applied during the electroplating cycle, some of the conductive material adhered to the mouth regions of the openings can be electrolyzed (become re-dissolved). This avoids blocking the mouth of openings during filling the openings and the formation of voids inside the bump, thus preventing the lowering of the bump height after a reflow process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A process for fabricating bumps, comprising the steps of:
providing a wafer having a plurality of bonding pads and a passivation layer thereon, wherein the passivation layer is disposed on a surface of the wafer and exposes the bonding pads;
forming a photoresist layer over the wafer, wherein the photoresist layer has a plurality of openings with different widths and the openings are positioned corresponding to the bonding pads;
immersing the wafer into an electrolytic solution; and
performing an electroplating operation by providing an increasing step current to the electrolytic solution.

2. The bump fabrication process of claim 1, wherein the increasing step current is set between Iₘᵢₙ and Iₘₐₓ, wherein Iₘᵢₙ is a smallest current to start the electroplating operation and Iₘₐₓ is a largest permissible current for performing the electroplating operation.

3. The bump fabrication process of claim 1, wherein the step current comprises a plurality of linear currents.

4. The bump fabrication process of claim 3, wherein the step of performing an electroplating operation further comprises stopping providing the step current for a brief period, so that the electroplating operation is temporarily suspended.

5. The bump fabrication process of claim 1, wherein the step current comprises a plurality of pulse currents, each having a peak current and a trough current.

6. The bump fabrication process of claim 5, wherein the peak current is set between Iₘᵢₙ and Iₘₐₓ.

7. The bump fabrication process of claim 5, wherein the trough current is selected from the group consisting of a positive current smaller than Iₘᵢₙ, a zero current and a negative current.

8. The bump fabrication process of claim 1, wherein the step current comprises at least a pulse current and a plurality of linear currents and the pulse current comprises a peak current and a trough current.

9. The bump fabrication process of claim 8, wherein the peak current is set between Iₘᵢₙ and Iₘₐₓ.

10. The bump fabrication process of claim 8, wherein the trough current is selected from the group consisting of a positive current smaller than Iₘᵢₙ, a zero current and a negative current.
